(19) United States
(12) Patent Application Publication
(10) Pub. No.: US 2016/0211358 A1
(43) Pub. Date: Jul. 21, 2016

(54) SEMICONDUCTOR DEVICE

(71) Applicant: KABUSHIKI KAISHA TOSHIBA, Tokyo (JP)

(72) Inventors: Hung HUNG, Nonoichi Ishikawa (JP); Yasuhiro ISOBE, Kanazawa Ishikawa (JP); Akira YOSHIOKA, Nomi Ishikawa (JP)

(21) Appl. No.: 14/831,488

(22) Filed: Aug. 20, 2015

(30) Foreign Application Priority Data
Jan. 21, 2015 (JP) 2015-009596

(51) Int. Cl. H01L 29/778; H01L 29/205; H01L 29/66; H01L 29/10; H01L 21/02; H01L 29/207; H01L 29/20; H01L 29/36

(52) U.S. Cl. CPC H01L 29/7787; H01L 29/2003; H01L 29/205; H01L 29/36; H01L 29/1029; H01L 21/02458; H01L 21/0254; H01L 29/207; H01L 21/0262; H01L 29/66462

(57) ABSTRACT

A semiconductor device includes a first semiconductor layer on a substrate, a second semiconductor layer on the first semiconductor layer, the second semiconductor layer including a nitride semiconductor doped with carbon, a third semiconductor layer on the second semiconductor layer, the third semiconductor layer including a nitride semiconductor doped with indium, and a fourth semiconductor layer on the third semiconductor layer, the fourth semiconductor layer including a nitride semiconductor having a band gap larger than a band gap of the third semiconductor layer. The concentration of indium in the third semiconductor layer is higher than 1×10¹⁸ cm⁻³ and lower than 1×10¹⁹ cm⁻³.

### CROSS-REFERENCE TO RELATED APPLICATION

This application is based upon and claims the benefit of priority from Japanese Patent Application No. 2015-009596, filed Jan. 21, 2015, the entire contents of which are incorporated herein by reference.

### FIELD

An embodiment described herein relates to a semiconductor device, and more particularly to a semiconductor device which uses a compound semiconductor.

### BACKGROUND

A power semiconductor element such as a switching element or a diode is used in a switching power source and a circuit such as an inverter. Such a power semiconductor element is required to possess high breakdown strength (high breakdown voltage) and low ON resistance. Although there is a trade-off relationship between the breakdown strength and the ON resistance, based in part on the device material, such trade-off relationship based on the material may be improved by using a wide band gap semiconductor such as a nitride semiconductor or silicon carbide (SiC) as the device element material compared to the case where silicon is used as a device element material, thus providing a power semiconductor element having a high breakdown strength and a low ON resistance.

A nitride semiconductor such as GaN or AlGaN possesses excellent material characteristics for forming a power semiconductor device and hence, a power semiconductor device element having high performance may be created therewith. Particularly, in a HEMT (High Electron Mobility Transistor) having the heterojunction structure of AlGaN/GaN, a two-dimensional electron gas having a high concentration is generated adjacent to the boundary between an AlGaN layer and a GaN layer by polarization and hence, the HEMT may realize a low ON resistance.

### DESCRIPTION OF THE DRAWINGS

FIG. 1 is a cross-sectional view of a semiconductor device according to an embodiment.

### DETAILED DESCRIPTION

According to an embodiment, there is provided a semiconductor device having increased electron mobility, and also reduced occurrence of current collapse.

In general, according to one embodiment, a semiconductor device includes: a first semiconductor layer on a substrate; a second semiconductor layer on the first semiconductor layer, the second semiconductor layer including a nitride semiconductor doped with carbon; a third semiconductor layer on the second semiconductor layer, the third semiconductor layer including a nitride semiconductor doped with indium; and a fourth semiconductor layer on the third semiconductor layer, the fourth semiconductor layer including a nitride semiconductor having a band gap larger than a band gap of the third semiconductor layer. A concentration of indium in the third semiconductor layer is greater than 1×10¹⁸ cm⁻³and lower than 1×10¹⁹ cm⁻³.

Hereinafter, an embodiment is explained by reference to drawings. The drawings are schematic or conceptual views and hence, sizes and ratios of the respective components in the respective drawings are not always equal to those of an actual semiconductor device. The embodiment described hereinafter merely exemplify a device and a method for embodying the technical aspects of the present disclosure, and the technical aspects of the present disclosure is not limited by shapes, structures, dispositions and the like of structural components described in the embodiment. In the explanation made hereinafter, structural elements having the substantially identical functions or structures are given same symbols, and these structural elements are explained repeatedly only when such explanation is necessary.

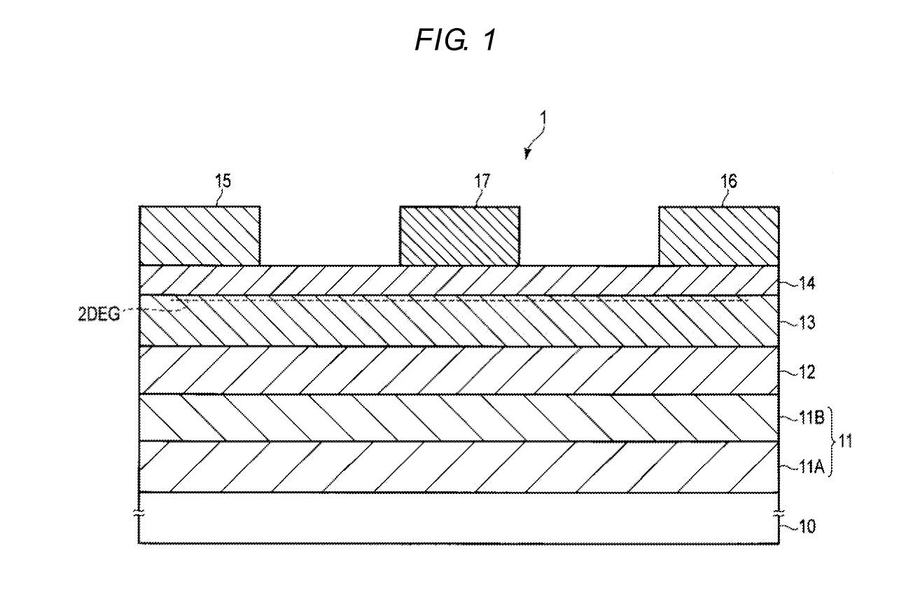

FIG. 1 is a cross-sectional view of a semiconductor device 1 according to the embodiment. The semiconductor device 1 is a nitride semiconductor device where a compound nitride semiconductor is used. The semiconductor device 1 is a Field Effect Transistor (FET). Specifically, the semiconductor device 1 is a HEMT (High Electron Mobility Transistor).

A substrate 10 is formed of a silicon (Si) substrate where a (111) plane forms a main plane thereof, for example. As a material for forming the substrate 10, silicon carbide (SiC), gallium nitride (GaN), gallium phosphide (GaP), indium phosphide (InP), gallium arsenide (GaAs), sapphire (Al₂O₃) or the like may also be used. A substrate which includes an insulating layer maybe used as the substrate 10. For example, an SOI (Silicon On Insulator) substrate may be used as the substrate 10.

A buffer layer 11 is formed on the substrate 10. The buffer layer 11 has a function of alleviating strain caused by the difference between the lattice constant of a nitride semiconductor layer formed on the buffer layer 11 and the lattice constant of the substrate 10, and also has the function of controlling the crystallinity of the nitride semiconductor layer formed on the buffer layer 11. The buffer layer 11 is made of AlₓGa₁₋ₓN, where 0≦X≦1, for example.

The buffer layer 11 may be formed by stacking or depositing, such as by epitaxial growth, a plurality of layers made of AlₓGa₁₋ₓN which have different composition ratios, one over the other. When the buffer layer 11 is formed by such a stacked structure, composition ratios of the layers in the stacked structure are adjusted such that the lattice constants of a plurality of layers which form the stacked structure are incrementally changed from a lattice constant of the layer disposed below the buffer layer 11 to the lattice constant of the layer disposed above the buffer layer 11 with respect to the layers which interpose the buffer layer 11 therebetween. In this embodiment, as shown in FIG. 1, the buffer layer 11 has a stacked structure formed of an AlGaN layer 11A and an undoped GaN layer 11B, for example. “Undoped” means that a layer is not intentionally doped with a dopant or impurity. For example, a small amount of dopant which is unintentionally incorporated into the layer during a manufacturing step or the like falls within the meaning of the term “undoped”. A thickness of the GaN layer 11B is approximately 1 μm, for example.

A high resistance layer 12 is formed on the buffer layer 11. The high resistance layer 12 has a function of improving the breakdown strength of the semiconductor device 1. That is, by forming the high resistance layer 12 on the buffer layer 11, a breakdown resistance voltage corresponding to the resistance of the high resistance layer 12 is created by the high resistance layer 12 and hence, the breakdown strength of the semiconductor device 1 may be improved by an amount corresponding to the breakdown voltage value of the high resistance layer. The resistance of the high resistance layer 12 is greater than the resistance of the buffer layer 11. The high resistance layer 12 is made of AlₓIn_{y}Ga_{1-(X+Y)}N, where 0≦X<1, 0≦Y<1, 0≦X+Y<1 doped with carbon (C). In this embodiment, the high resistance layer 12 is made of GaN (C—GaN) doped with carbon (C), for example. A thickness of the high resistance layer 12 is approximately 2 μm, for example. The resistance of the high resistance layer 12 is selected as desired corresponding to a breakdown strength which the semiconductor device 1 is desired to possess.

A channel layer 13 is formed on the high resistance layer 12. The channel layer 13 is a layer in which a channel (current pathway) of the transistor is formed. The channel layer 13 is made of a nitride semiconductor having favorable crystallinity (a high-quality nitride semiconductor). The specific structure of the channel layer 13 is described later.

A barrier layer 14 is formed on the channel layer 13. The barrier layer 14 is made of AlₓIn_{y}Ga_{1-(X+Y)}N, where 0≦X<1, 0≦Y<1, 0≦X+Y<1. The barrier layer 14 is made of a nitride semiconductor having a band gap larger than a band gap of a material for forming the channel layer 13. In this embodiment, the barrier layer 14 is made of undoped AlGaN, for example. A composition ratio of Al in the AlGaN layer forming the barrier layer 14 is approximately 0.2, for example. A thickness of the barrier layer 14 is approximately 30 nm, for example.

The plurality of semiconductor layers forming the semiconductor device 1 are sequentially formed by epitaxial growth using an MOCVD (Metal Organic Chemical Vapor Deposition) method, for example. That is, the plurality of semiconductor layers forming the semiconductor device 1 are formed of epitaxial layers.

A source electrode 15 and a drain electrode 16 are formed on the barrier layer 14 and spaced from each other. A gate electrode 17 is formed on the barrier layer 14 between the source electrode 15 and the drain electrode 16 such that the gate electrode 17 is spaced from the source electrode 15 and the drain electrode 16.

The gate electrode 17 and the barrier layer 14 form a Schottky junction. That is, the gate electrode 17 contains a material by which the gate electrode 17 forms a Schottky junction with the barrier layer 14. The semiconductor device 1 shown in FIG. 1 is a Schottky-barrier HEMT. The gate electrode 17 is formed from a layer stack of Au/Ni, for example. The material on a left side of the “/” is the material forming an upper layer of the electrode, and the material on the right side of the “/” is the material forming a lower layer of the electrode. The semiconductor device 1 is not limited to the Schottky-barrier HEMT, and may be an MIS (Metal Insulator Semiconductor) HEMT where a gate insulating film is interposed between the barrier layer 14 and the gate electrode 17.

The source electrode 15 and the barrier layer 14 are in ohmic contact with each other. In the same manner, the drain electrode 16 and the barrier layer 14 are in ohmic contact with each other. That is, the source electrode 15 and the drain electrode 16 respectively contain a material so that the source electrode 15 and the drain electrode 16 form an ohmic contact with the barrier layer 14. The source electrode 15 and the drain electrode 16 have the stacked structure of Al/Ti respectively, for example.

In the hetero junction structure formed of the channel layer 13 and the barrier layer 14, the lattice constant of the barrier layer 14 is smaller than the lattice constant of the channel layer 13 and hence, strain is generated in the barrier layer 14. Due to a piezoelectric effect generated by such strain, a piezoelectric polarization is generated in the barrier layer 14 and hence, a two-dimensional electron gas (2DEG) is generated in the vicinity of a boundary between the channel layer 13 and the barrier layer 14. The two-dimensional electron gas is in the channel layer 13 and provides at least part of the channel between the source electrode 15 and the drain electrode 16. Due to a Schottky barrier generated by a Schottky junction between the gate electrode 17 and the barrier layer 14, current through the channel between the source and drain may be controlled by the voltage on the gate electrode 17. Further, the two-dimensional electron gas possesses high electron mobility and hence, the semiconductor device 1 may perform extremely high-speed switching operations.

The semiconductor device 1 is formed as described above. The semiconductor device 1 is a normally-on type semiconductor device, for example. When the semiconductor device 1 is in an ON state, for example, a voltage of 0 V is applied to the gate electrode 17, a voltage of 0 V is applied to the source electrode 15, and a high voltage (for example, 200 V) is applied to the drain electrode 16. When the semiconductor device 1 is in an ON state, drain current flows between the drain electrode 16 and the source electrode 15 through the channel formed in the channel layer 13.

When the semiconductor device 1 is in an OFF state, for example, a negative voltage (for example, −15 V) is applied to the gate electrode 17, a voltage of 0 V is applied to the source electrode 15, and a voltage of 200 V is applied to the drain electrode 16. When the semiconductor device 1 is in an OFF state, the thickness of a depletion layer which extends below the gate electrode 17 is controlled so that the drain current is blocked.

### (Structure of Channel Layer 13)

Next, the specific structure of the channel layer 13 is explained. The channel layer 13 is made of GaN (gallium nitride). A thickness of the channel layer 13 is approximately 1 μm, for example. The GaN layer forming the channel layer 13 is doped with indium (In) using trimethlyindium as an indium source gas. In the GaN layer (In—GaN layer) doped with indium (In), the concentration of indium is set to a value which is larger than 1×10¹⁸cm⁻³and smaller than 1×10¹⁹ cm⁻³. By setting the concentration of indium to a value which satisfies the above-mentioned condition, the deterioration of the crystallinity, i.e., the occurrence of defects and irregularities in the crystal structure of the channel layer 13, may be prevented.

In forming a GaN layer by epitaxial growth using an MOCVD method, carbon molecules in trimethylgallium (TMGa) which is a Ga precursor material enters the GaN crystals so that a concentration of dopants in GaN crystal is increased whereby the trap density in the band gap is increased. The higher the growth speed of the GaN layer, the larger the flow rate of TMGa required, and the crystallinity of GaN crystal is remarkably deteriorated by the inclusion of the carbon dopant, i.e., the crystal is distorted and there are more defects in the crystal structure. On the other hand, by adding indium (In) in the GaN layer by doping indium during growing of the GaN layer, the carbon concentration in GaN crystal grown using trimethylgallium is lowered and hence, the surface roughness of the GaN crystal is decreased.

In this embodiment, the channel layer 13 is doped with indium (In) to reduce the quantity of carbon doped into the crystal. By reducing the carbon dopant level in the crystal, the concentration of carbon in the channel layer 13 is lowered. To be more specific, the concentration of carbon in the channel layer 13 is provided at a value smaller than or equal to 1×10¹⁸ cm⁻³.

As described above in detail, according to this embodiment, the channel layer 13 is doped with indium (In) so that the concentration of carbon in the channel layer 13 may be lowered. By lowering the concentration of carbon in the channel layer 13, the deterioration of the crystalline structure of the channel layer 13 maybe prevented. As a result, electron and hole mobility in the semiconductor device 1 may be further improved.

Further, a concentration of dopant (that is, a concentration of carbon) in the channel layer 13 is lowered and hence, traps in the band gap caused by the presence of carbon will be reduced. Due to such reduction of traps, a current collapse phenomenon (a phenomenon that a drain current is lowered while the semiconductor device operates) maybe further reduced. Further, the breakdown strength (breakdown voltage) of the channel layer 13 will be enhanced. Accordingly, the operational characteristic of the semiconductor device 1 may be enhanced.

In this disclosure, “stack” means not only a state where layers are made to overlap with each other in a contact manner but also a state where layers are made to overlap with each other with another layer interposed therebetween. Further, “formed on” or “located on” means not only a state where a layer is directly formed or located on a layer but also a state where a layer is formed or located on a layer with another layer interposed therebetween.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a first semiconductor layer on a substrate;
a second semiconductor layer on the first semiconductor layer, the second semiconductor layer comprising a nitride semiconductor doped with carbon;
a third semiconductor layer on the second semiconductor layer, the third semiconductor layer comprising a nitride semiconductor doped with indium; and
a fourth semiconductor layer on the third semiconductor layer, the fourth semiconductor layer comprising a nitride semiconductor having a band gap larger than a band gap of the third semiconductor layer, wherein
a concentration of indium in the third semiconductor layer is higher than 1×10¹⁸ cm⁻³ and lower than 1×10¹⁹ cm⁻³.

2. The semiconductor device according to claim 1, wherein a concentration of carbon in the third semiconductor layer is 1×10¹⁸ cm⁻³ or lower.

3. The semiconductor device according to claim 1, wherein the third semiconductor layer comprises GaN.

4. The semiconductor device according to claim 1, wherein the second semiconductor layer comprises Al In_{y}Ga_{1-(X+Y)}N, where 0≦X<1, 0≦Y<1, 0≦X+Y<1.

5. The semiconductor device according to claim 1, wherein the fourth semiconductor layer comprises Al In_{y}Ga_{1-(X+Y)}N, where 0≦X<1, 0≦Y<1, 0≦X+Y<1.

6. The semiconductor device according to claim 1, wherein the third and the fourth semiconductor layers have different lattice constants.

7. The semiconductor device of claim 6, wherein a two dimensional electron gas is formed at the interface of the third and fourth semiconductor layers.

8. The semiconductor device of claim 7, further comprising a gate electrode on the fourth semiconductor layer, wherein each of a source electrode and a drain electrode is disposed on opposite sides of the gate electrode and contacting the fourth semiconductor layer.

9. The semiconductor device of claim 8, wherein the third semiconductor layer provides a channel between the source and drain.

10. The semiconductor device of claim 9, wherein application of a negative voltage on the gate electrode forms a depletion region in the third semiconductor layer which disrupts the two dimensional electron gas.

11. A method of forming a semiconductor device, comprising:
forming a first semiconductor layer on a substrate;
forming a second semiconductor layer on the first semiconductor layer, the second semiconductor layer comprising a carbon doped nitride semiconductor;
forming a third semiconductor layer on the second semiconductor layer, the third semiconductor layer comprising an indium doped nitride semiconductor; and
forming a fourth semiconductor layer on the third semiconductor layer, the fourth semiconductor layer comprising a nitride semiconductor having a band gap larger than the band gap of the third semiconductor layer, wherein
a concentration of indium in the third semiconductor layer is greater than 1×10¹⁸ cm³ and less than 1×10¹⁹ cm⁻³.

12. The method of forming a semiconductor device of claim 11, wherein a concentration of carbon in the third semiconductor layer is 1×10¹⁸ cm⁻³ or lower.

13. The method of forming a semiconductor device of claim 11, wherein the third semiconductor layer comprises GaN.

14. The method of forming a semiconductor device of claim 11, wherein the second semiconductor layer comprises AlₓIn_{y}Ga_{1-(X+Y)}N, where 0≦X<1, 0≦Y<1, 0≦X+Y<1.

15. The method of forming a semiconductor device of claim 11, wherein the fourth semiconductor layer is a nitride semiconductor layer comprising AlₓIn_{y}Ga_{1-(X+Y)}N, where 0≦X<1, 0≦Y<1, 0≦X+Y<1.

16. The method of forming a semiconductor device according to claim 11, wherein the third and the fourth semiconductor layers have different lattice constants.

17. A method of forming a semiconductor device, comprising:
forming a first semiconductor layer on a substrate;
forming a second semiconductor layer on the first semiconductor layer, the second semiconductor layer comprising a carbon doped nitride semiconductor;
forming a third semiconductor layer on the second semiconductor layer, the third semiconductor layer comprising an indium doped gallium nitride semiconductor; and
forming a fourth semiconductor layer on the third semiconductor layer, the fourth semiconductor layer comprising a nitride semiconductor having a band gap larger than the band gap of the third semiconductor layer, wherein
at least the third layer is formed by epitaxially growing the third layer on the second layer using trimethylgallium as a source gas and a concentration of indium in the third semiconductor layer is greater than 1×10¹⁸ cm⁻³ and less than 1×10¹⁹ cm⁻³.

18. The method of forming a semiconductor device of claim 17, wherein a concentration of carbon in the third semiconductor layer is 1×10¹⁸ cm⁻³ or lower.

19. The method of forming a semiconductor device of claim 17, wherein the third semiconductor layer comprises GaN.

20. The method of forming a semiconductor device of claim 17, wherein the second semiconductor layer comprises AlₓIn_{y}Ga_{1-(X+Y)}N, where 0≦X<1, 0<X+Y<1.
